(19) United States
(12) Patent Application Publication
(10) Pub. No.: US 2008/0309329 A1
(43) Pub. Date: Dec. 18, 2008

(54) On-Chip Magnetic Sensor Device with Suppressed Cross-Talk

(75) Inventors: Josephus Arnoldus Henricus Maria Kahlman, Eindhoven (NL); Bart Michiel De Boer, Eindhoven (NL); Menno Willem Jose Prins, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIKE PHILIPS ELECTRONICS N.V., EINDHOVEN (NL)

(21) Appl. No.: 10/597,639

(22) PCT Filed: Jul. 29, 2004
(86) PCT No.: PCT/IB04/51329

§ 371 Date: Aug. 2, 2006

(51) Int. Cl. G01R 33/12

(52) U.S. Cl. 324/228

(57) ABSTRACT

A magnetic sensor device is disclosed for the detection or determination of a magnetic field, such as for example, but not limited to, the presence of magnetic particles (15). In particular it relates to an integrated or on-chip magnetic sensor element (11) for the detection of magnetic nano-particles functioning as a label to biological molecules. The device of the present invention offers reduced cross-talk between the magnetic sensor element (11) and a magnetic field generator (12) by compensating capacitive and/or magnetic coupling for instance by using an electrostatic shield and/or modulation and demodulation techniques. The device may be used for magnetic detection of binding of biological molecules on a micro-array or biochip.

The invention relates to a magnetic sensor device comprising a magnetic sensor element on a substrate, at least one magnetic field generator for generating a magnetic field on the substrate.

The invention further relates to the use of such a device for molecular diagnostics biological sample analysis, or chemical sample analysis.

The introduction of micro-arrays or biochips is revolutionizing the analysis of samples for DNA (desoxyribonucleic acid), RNA (ribonucleic acid), proteins, cells and cell fragments, tissue elements, etc. Applications are e.g. human genotyping (e.g. in hospitals or by individual doctors or nurses), bacteriological screening, biological and pharmacological research.

Biochips, also called biosensor chips, biological microchips, gene-chips or DNA chips, consist in their simplest form of a substrate on which a large number of different probe molecules are attached, on well defined regions on the chip, to which molecules or molecule fragments that are to be analyzed can bind if they are perfectly matched. For example, a fragment of a DNA molecule binds to one unique complementary DNA (c-DNA) molecular fragment. The occurrence of a binding reaction can be detected, e.g. by using fluorescent markers that are coupled to the molecules to be analyzed. This provides the ability to analyze small amounts of a large number of different molecules or molecular fragments in parallel, in a short time. One biochip can hold assays for 10-1000 or more different molecular fragments. It is expected that the usefulness of information that can become available from the use of biochips will increase rapidly during the coming decade, as a result of projects such as the Human Genome Project, and follow-up studies on the functions of genes and proteins.

L. Lagae et al. describe in “On-chip manipulation and magnetization assessment of magnetic bead ensembles by integrated spin-valve sensors”, Journal of Applied Physics, Vol. 91, number 10, pp. 7445-7447, 15 May 2002, a spin-valve sensor integrated with magnetic field generating conductors to assess the behavior of ensembles of superparamagnetic nano-particles. Two tapered current lines are integrated at both sides of the spin-valve sensor. With these on-chip current lines, magnetic fields are generated that magnetize the nano-particles in the vicinity of these conductors. The magnetizing fields of the current lines are orthogonal to the sensing direction of the magnetic sensor and cannot saturate the sensor. Tapering of the current lines is necessary to generate a magnetic gradient force on the dipoles that moves the particles to the magneto-resistive sensor element. A pulse generator is used to apply 1 Hz alternating 50 mA pulses to the current lines. As soon as the currents are applied, the magnetic beads become magnetized and start to move towards the current line edges, driven by the gradient in the magnetic field. Once they reach the current line edges, they move along the edges towards the sensor and accumulate near the sensor. Due to the alternating pulses through both current lines, the particles are attracted alternately to each of the current lines and move over the sensor. A pulse amplitude of approximately 50 mA makes the magnetic particles cross the sensor at a maximum frequency of 2-3 Hz.

It is a problem that the magneto-resistive sensor element does not allow a sensitive detection in the mV or even μV range which is necessary to detect for instance a single magnetic particle functioning as a label for molecular diagnostics biological sample analysis, or chemical sample analysis.

It is an object of the present invention to provide a device of the type mentioned in the opening paragraph, the device resulting in a reduced cross-talk between the magnetic sensor element and the at least one magnetic field generator.

The object according to the invention is achieved in that cross-talk suppression means are present for suppressing cross-talk between the magnetic sensor element and the at least one magnetic field generator.

The invention is based on the insight that cross-talk is a limitation for the sensitivity of detection of small magnetic fields. The cross-talk can be subdivided in capacitive cross-talk and magnetic cross-talk. Reduction of the capacitive and/or the magnetic cross-talk is important, in particular when the measurement frequency increases. The on-going down-scaling of the dimensions on chips increases both the capacitive as well as the magnetic cross-talk.

The means for suppression cross-talk can be based on uncoupling of the capacitive coupling between the magnetic sensor element and the at least one magnetic field generator and/or the compensation of the magnetic cross-talk. For instance, a symmetric configuration of magnetic field generators around the magnetic sensor element can be useful to compensate magnetic cross-talk.

Preferably the magnetic sensor device is suited as a biosensor. In order to detect very small magnetic fields, such as the presence of at least one magnetic particle, the device further comprises a sensor circuit. The sensor circuit comprises the magnetic sensor element for sensing a magnetic property of the at least one magnetic particle which magnetic property is related to the generated magnetic field.

The cross-talk suppression means can comprise and electrostatic shielding device between the magnetic sensor element and the magnetic field generator. The electrostatic shield may be any device, which attenuates coupling between the conductor and the sensor. This electrostatic shield can be implemented by a conductive layer between conductor and sensor, which conductive layer is connected to a fixed voltage such as ground.

For a further reduction of cross-talk, the at least one magnetic field generator has a first frequency and the magnetic sensor element has a second frequency, wherein the cross-talk suppression means comprises electrical frequency distinguishing means for distinguishing between the first frequency and the second frequency. The electrical frequency distinguishing means can be e.g. a filter for filtering out unwanted signals or a demodulation technique.

Alternatively, the cross-talk suppression means can comprise electrical phase distinguishing means. In this embodiment the at least one magnetic field generator has a first frequency and a first phase. The magnetic sensor element has a DC sense current component. The output signal of the magnetic sensor element has the first frequency and a second phase. The second phase is equal to the first phase and an additional phase shift caused by the cross-talk. The electrical phase distinguishing means can distinguish between the first phase and the second phase. The electrical phase distinguishing means can be arranged such that a 90 degrees phase difference between the cross-talk and the demodulation phase of the desired output signal with the first phase is maintained. Because of this orthogonality in phase, the cross-talk is suppressed in a demodulated signal.

In order to be able to generate an ac magnetic field with a high frequency, a conductor integrated on the substrate is used through which an ac current is sent. The frequency of the alternating magnetic field can be much higher than in the prior art, where alternating pulses through both current lines are used, the particles are attracted alternately to each of the current lines and move over the sensor at a maximum frequency of 2-3 Hz.

The magnetic field generator and the sensing circuit can be integrated on one chip. This allows a very compact device. Moreover when a plurality of magnetic sensor elements are present for the detection of magnetic particles functioning as labels to biological molecules on an array or biochip, integration of all the connections to the sensor elements and the sensing circuits becomes much easier on chip than off chip. Thin film technologies allows multilevel metallization schemes and compact integrated circuit design.

The substrate can contain electronics that fulfill all detection and control functions (e.g. locally measurement of temperature and pH). This has the following advantages:

it makes the use of expensive and large (optical) detection devices unnecessary,

it provides the possibility to further enhance the areal density of probed molecules,

it enhances speed, accuracy and reliability,

it decreases the amount of test volume required, and

it decreases labor cost.

Biochips can become a mass product when they provide an absolutely inexpensive method for diagnostics, regardless of the venue (not only in hospitals but also at the sites of individual doctors), and when their use leads to a reduction of the overall cost of disease management.

Magneto-resistive sensors based on GMR and TMR elements can advantageously be used to measure slowly varying processes such as in the field of molecular diagnostics (MDx). Using magneto-resistive materials, a rugged, single-component, micro-fabricated detector may be produced, that will simultaneously monitor tens, hundreds, thousands or even millions of experiments.

In an advantageous embodiment the magnetic sensor element lies in a plane and there is a plurality of magnetic generators present.

The plurality of magnetic field generators can be located at different levels with respect to the plane of the magnetic sensor element.

It is a further object of the present invention to provide a method for detection of a magnetic field resulting in an improved sensitivity and a reduced cross-talk.

The method according to the invention is achieved in that cross-talk suppression means are used to reduce cross-talk between a magnetic sensor element and at least one magnetic field generator for generating a magnetic field.

When there is a plurality of magnetic generators present, the method can be used advantageously for determining a concentration of magnetic particles as a function of location of the magnetic particles, e.g. in a biological sample such a micro-array or biochip.

When the plurality of magnetic field generators are located at different levels with respect to the plane of the magnetic sensor element, the method allows the distinction and determination of the surface concentration and the bulk concentration of the magnetic particles. Further, the method is suitable to determine the position of the magnetic particles in a direction perpendicular to the plane of the magnetic sensor element, as well as the position parallel to a plane of the magnetic sensor element.

For accurate measurements, a calibration method can be applied. First the magnetic field generated by the magnetic field generator(s) is measured in absence of magnetic particles. The measurement value is subtracted from the actual measurement value obtained when a measurement is carried out in the presence of magnetic particles.

The calibrating measurement value can be stored in a memory, such as an MRAM, which can be electronically integrated with the magnetic sensor element and the sensing circuit on one chip.

These and other characteristics, features and advantages of the present invention will become apparent from the following detailed description, taken in conjunction with the accompanying drawings, which illustrate, by way of example, the principles of the invention. This description is given for the sake of example only, without limiting the scope of the invention. The reference figures quoted below refer to the attached drawings.

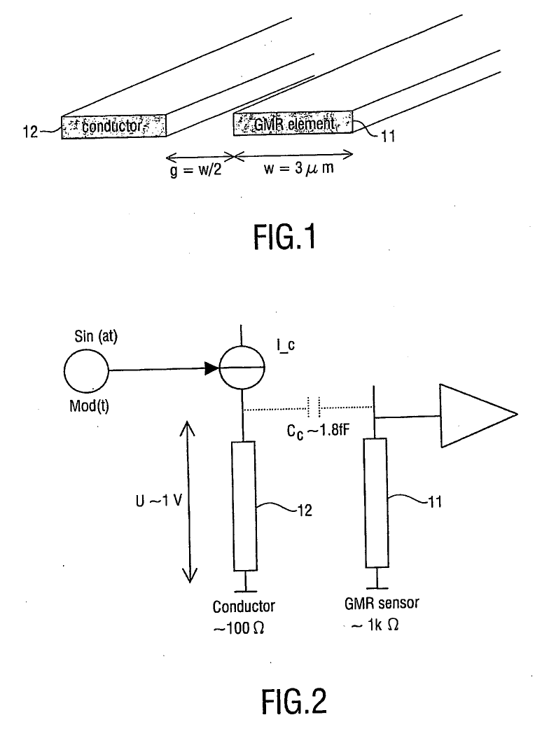

FIG. 1 shows schematically the magnetic sensor element and the magnetic field generator.

FIG. 2 illustrates capacitive cross-talk between the magnetic sensor element and the magnetic field generator.

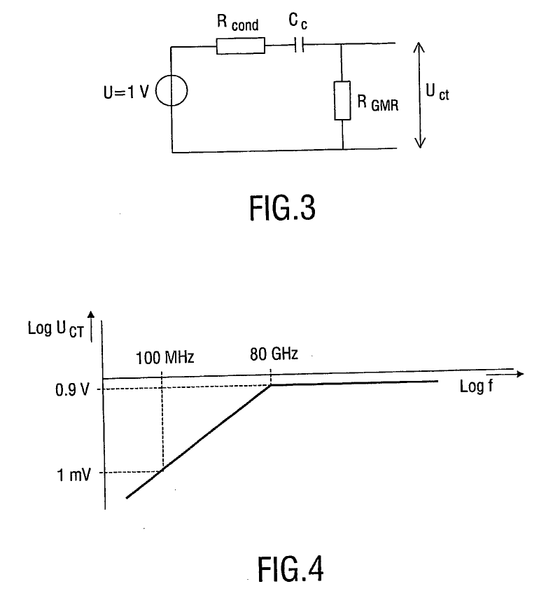

FIG. 3 shows the electrical equivalent scheme of FIG. 2.

FIG. 4 shows the Bode diagram corresponding to the electrical scheme of FIG. 3.

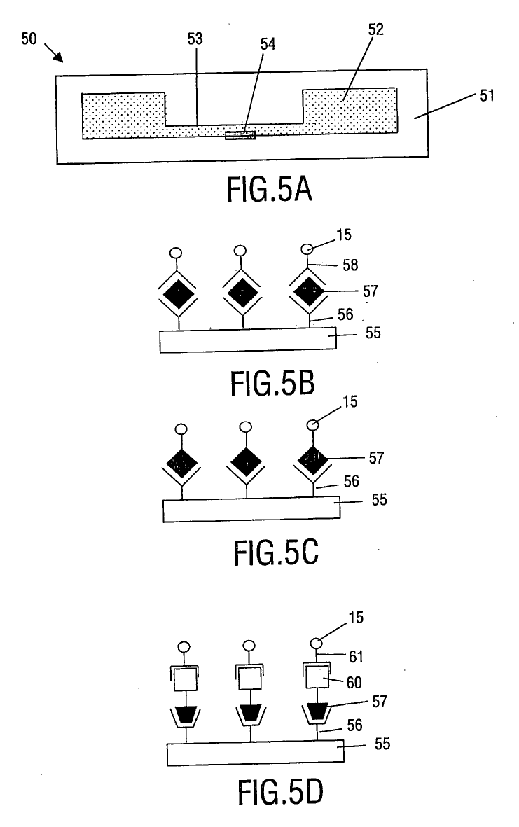

FIG. 5A shows a schematic representation of a biosensor device.

FIGS. 5B-D show details of a probe element provided with binding sites able to selectively bind target sample, and magnetic nano-particles being directly or indirectly bound to the target sample in different ways.

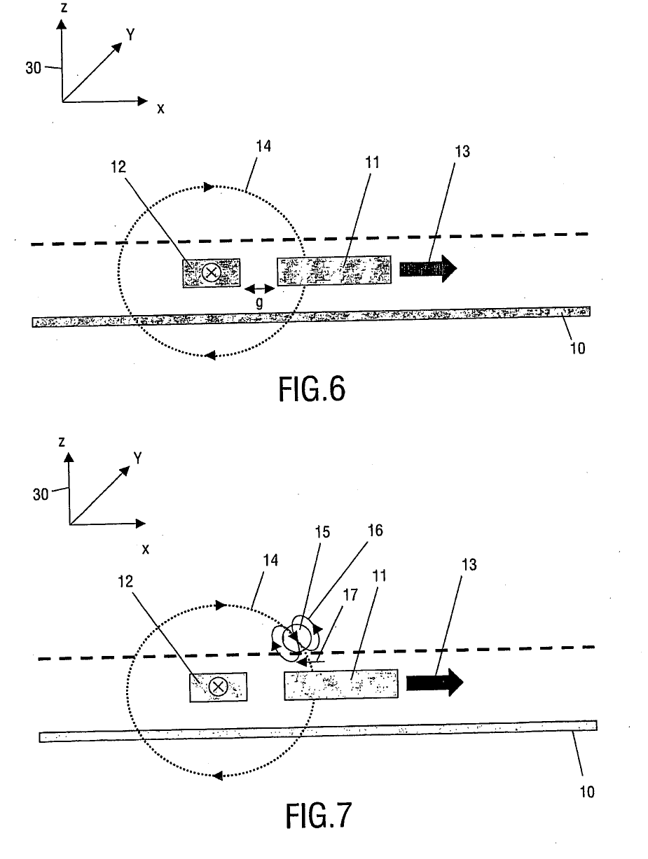

FIG. 6 is a cross-sectional view of a sensor device according to a first embodiment of the present invention in absence of magnetic particles.

FIG. 7 is a cross-sectional view of a sensor device according to the first embodiment of the present invention in the presence of magnetic particles.

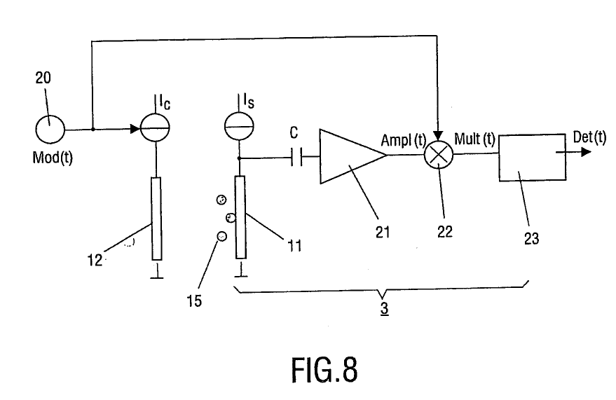

FIG. 8 is a schematic view of a detection method according to the first embodiment of the present invention without the presence of cross-talk suppression means.

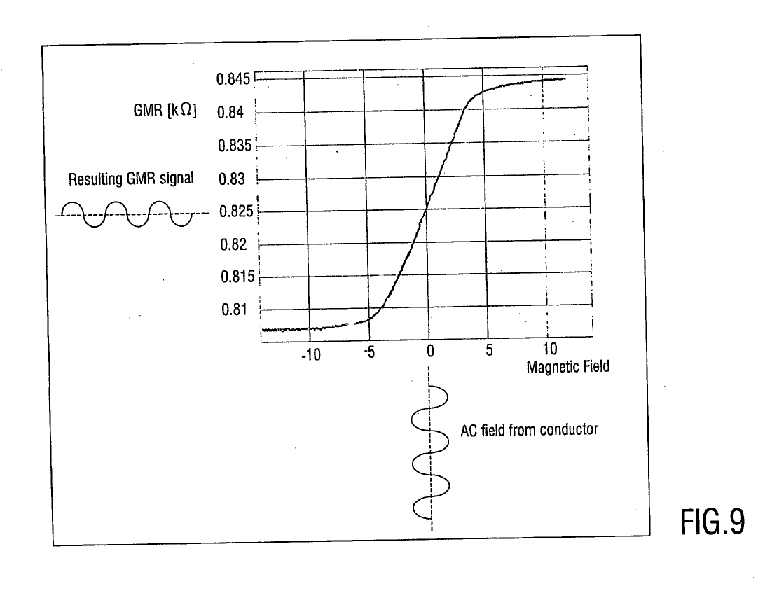

FIG. 9 shows the magnetoresistance characteristic of a GMR sensor element, the ac magnetic field, and the resulting GMR output signal.

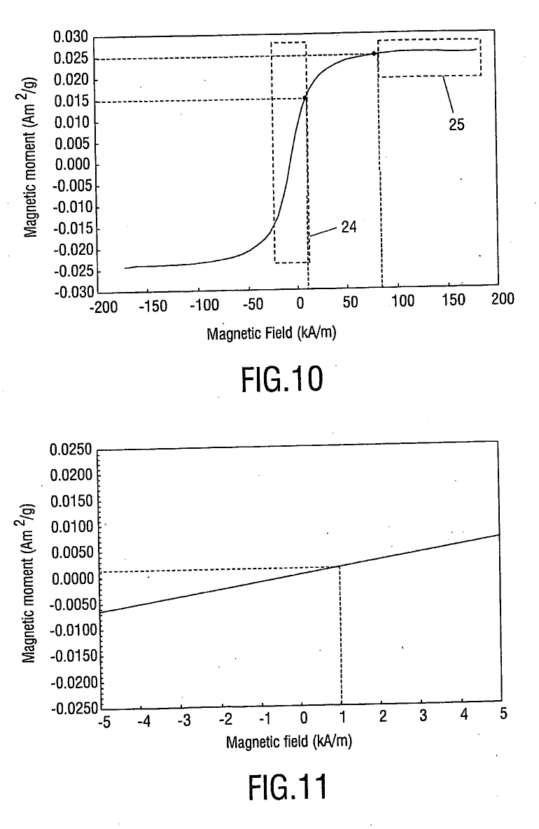

FIG. 10 is a graph of the magnetic moment of a magnetic nano-particle as a function of an applied magnetic field.

FIG. 11 is a detail of the magnetization curve of FIG. 10.

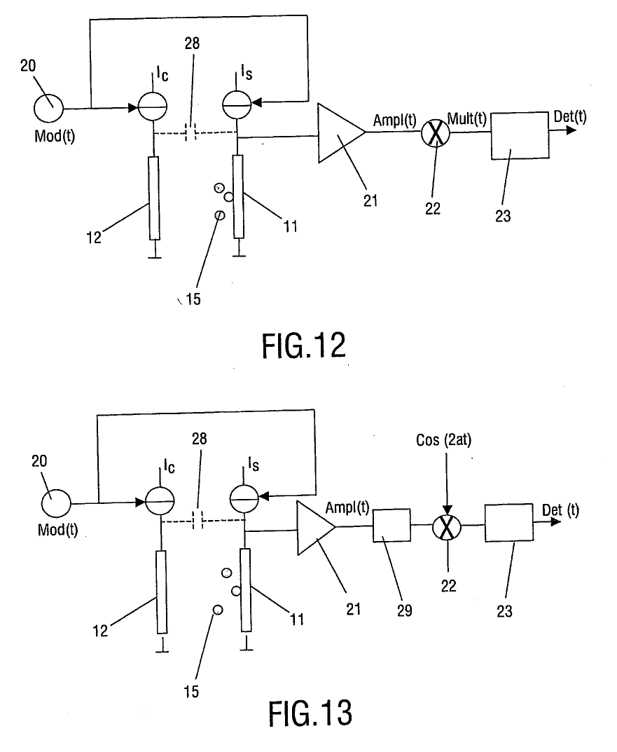

FIG. 12 is a schematic view of a detection method according to the first embodiment of the present invention in which the parasitic differential capacitor between the sensor and the conductor is uncoupled.

FIG. 13 is a schematic view of an alternative detection method as shown in FIG. 12 for additional suppression of 1/f noise.

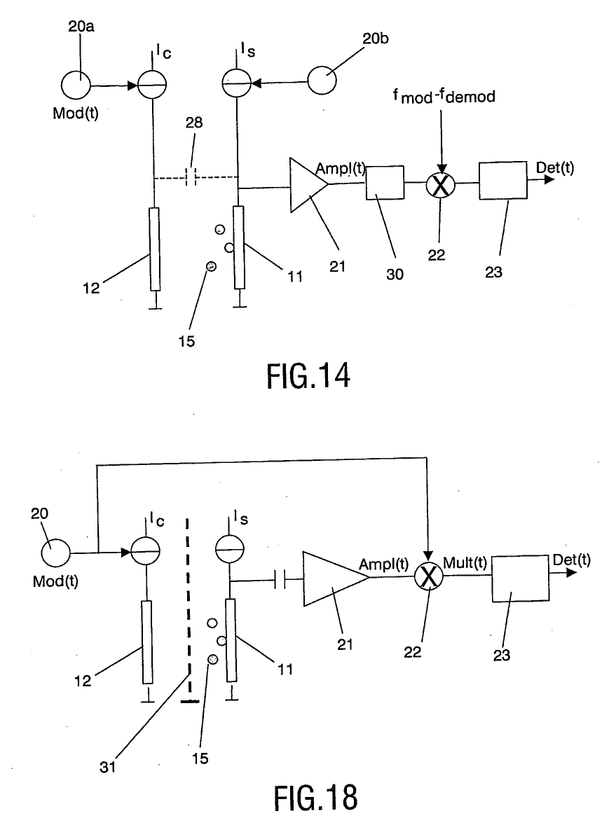

FIG. 14 shows a second embodiment of the present invention.

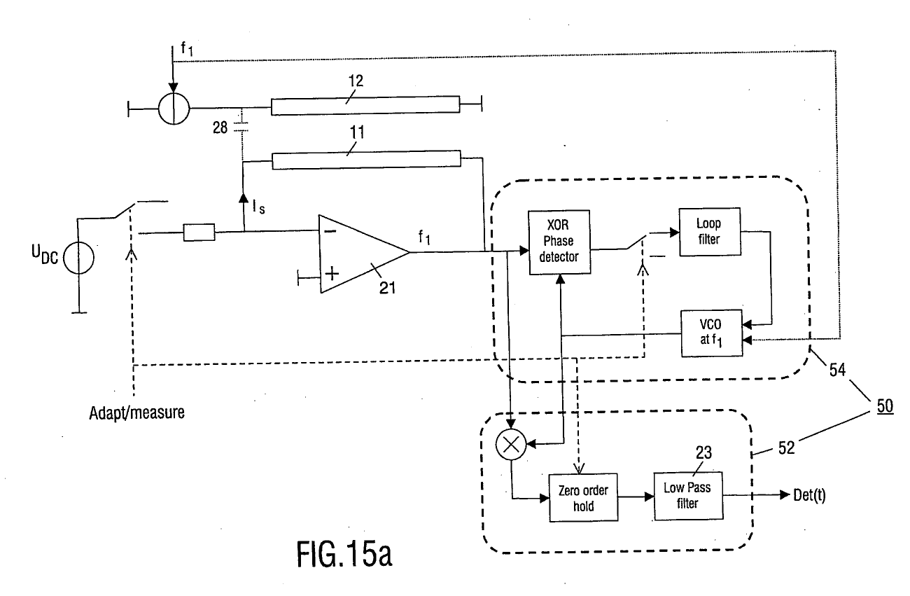

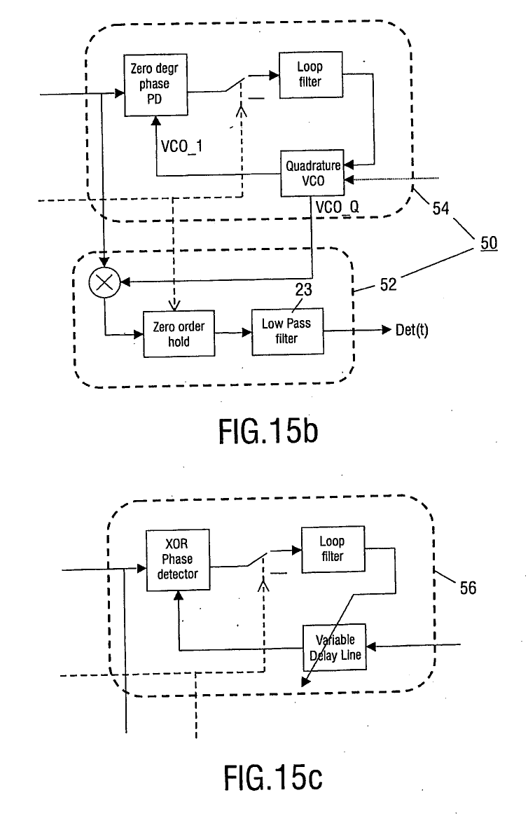

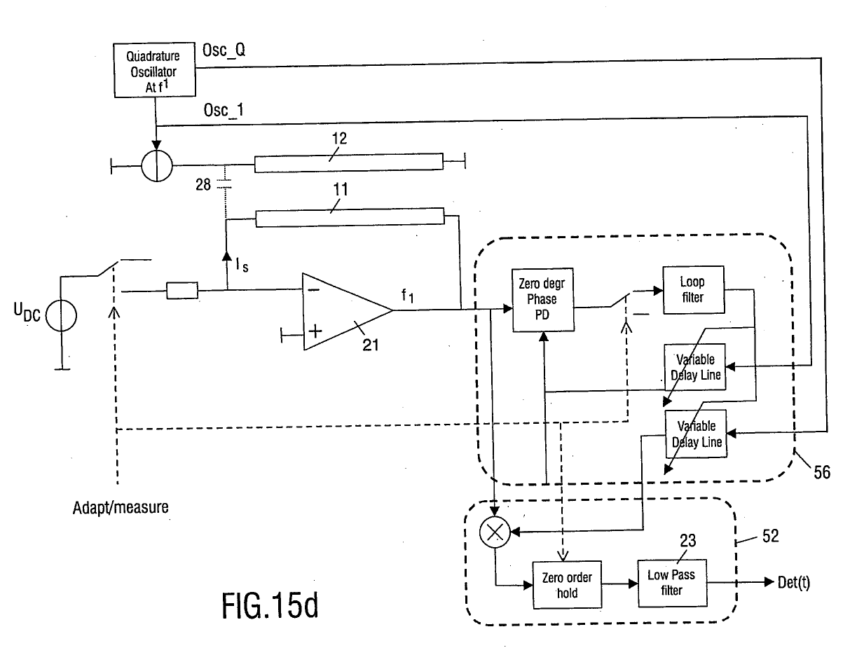

FIGS. 15A-D show various examples of a third embodiment of the invention, in which an alternative detection method is disclosed based on the separation in phase of the capacitive cross-talk signal and the desired magnetic signal.

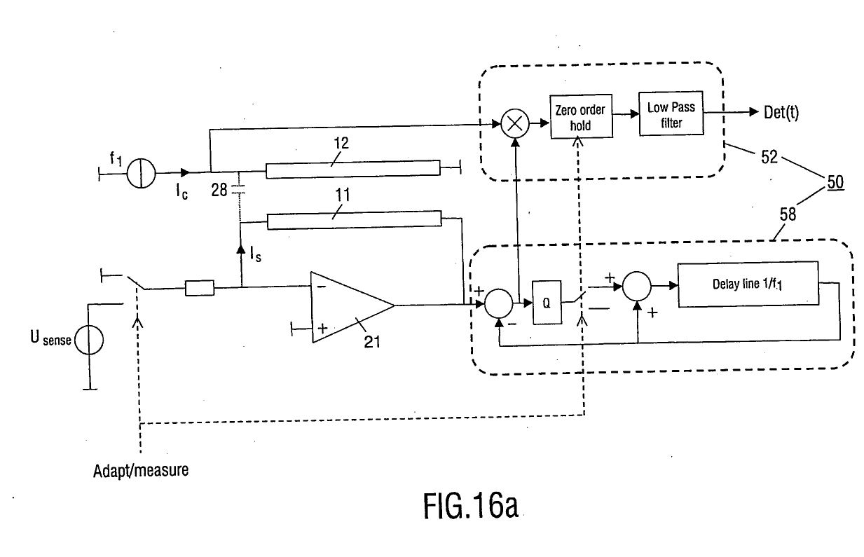

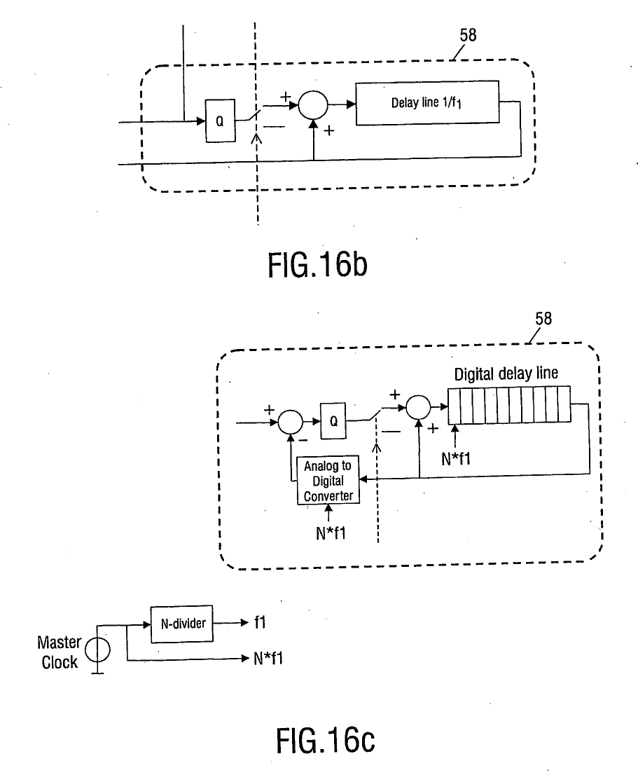

FIGS. 16A-C show another example of the third embodiment of the invention.

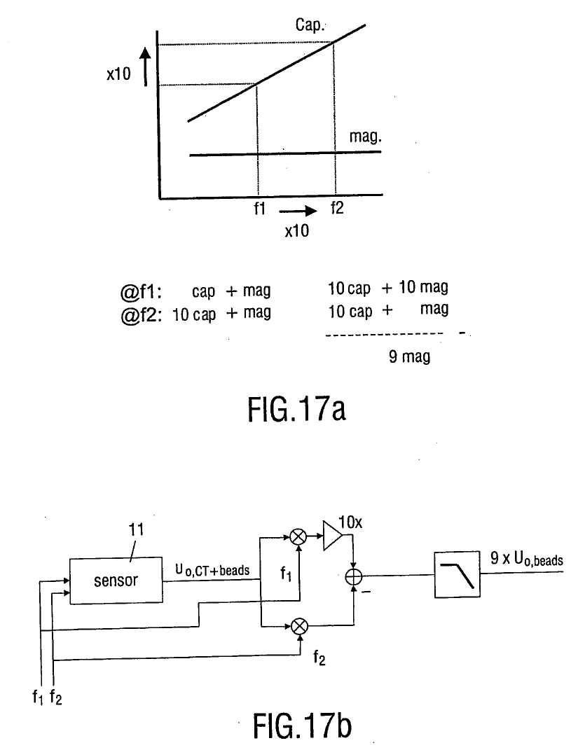

FIGS. 17A-B show a fourth embodiment of the invention, in which the capacitive cross talk subtraction is based on the difference in amplitude of the cross-talk signal as a function of frequency, whereas the amplitude of the desirable magnetic signal is almost independent of frequency.

FIG. 18 shows schematically the electrostatic shielding device between the magnetic sensor element and the magnetic field generator in a fifth embodiment of the present invention.

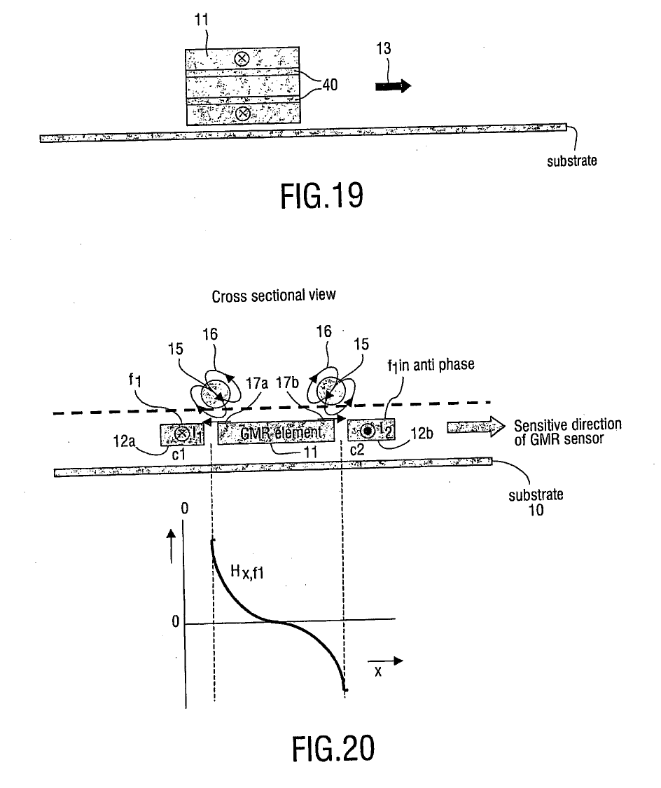

FIG. 19 shows an embodiment of the electrostatic shielding device.

FIG. 20 shows a cross sectional view of a combination of a magnetic sensor with two conductors as used in an sixth embodiment of the present invention for compensating cross-talk.

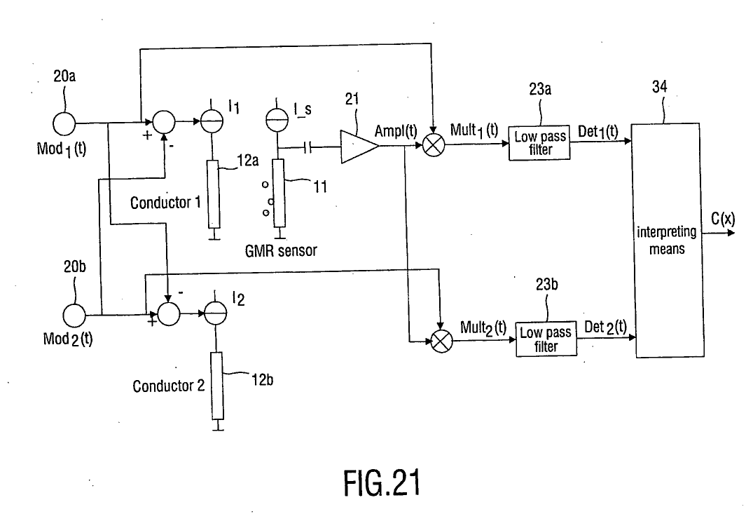

FIG. 21 is a schematic view of a detection method for use with the sensor device according to the sixth embodiment of the present invention.

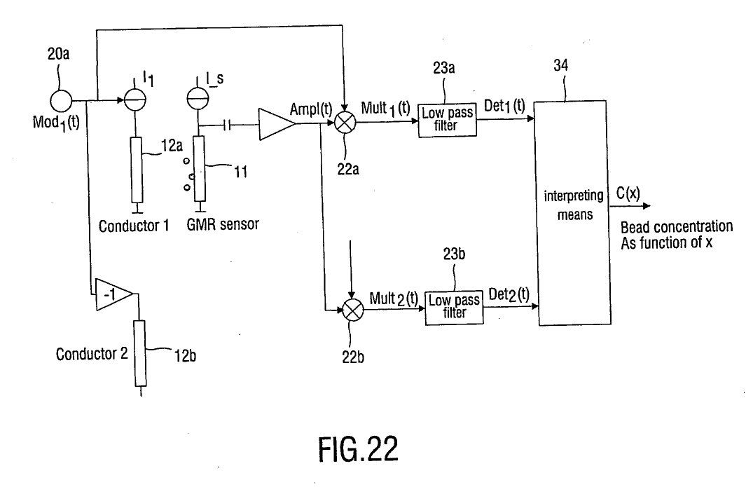

FIG. 22 shows a seventh embodiment for capacitive cross-talk cancelling without affecting the magnetic field.

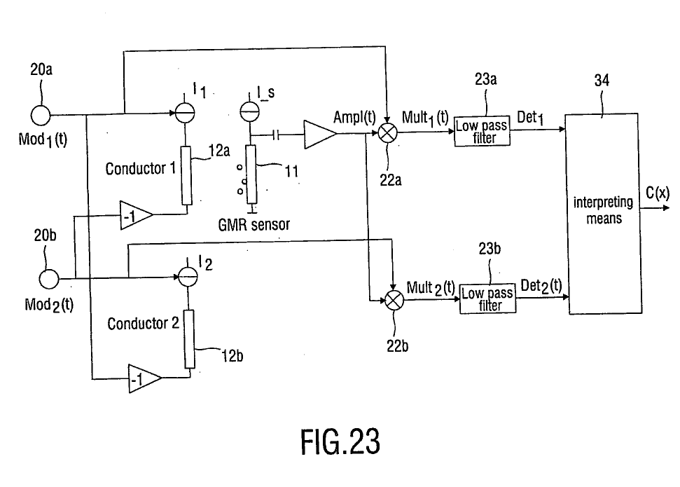

FIG. 23 shows a eighth embodiment for capacitive cross-talk cancelling without affecting the magnetic field.

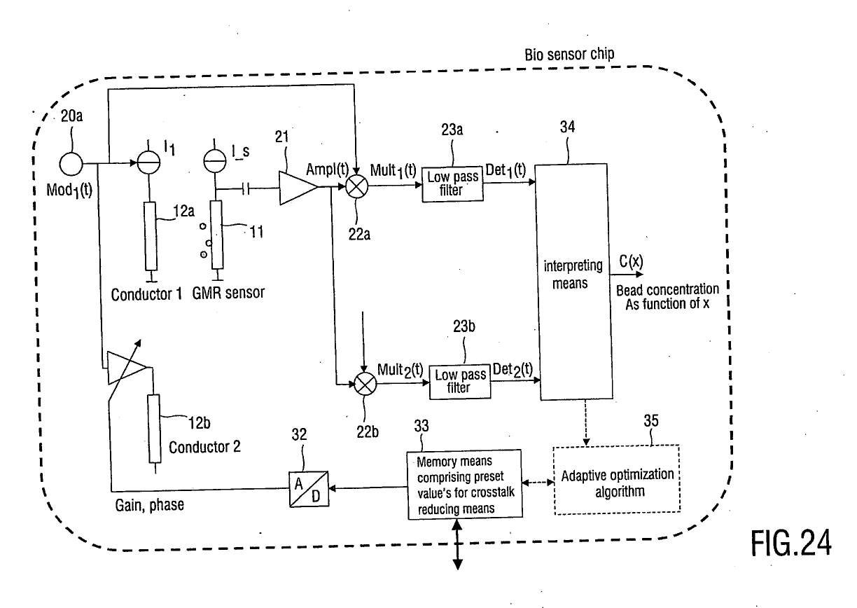

FIG. 24 shows a ninth embodiment for on-chip storage of cross-talk settings.

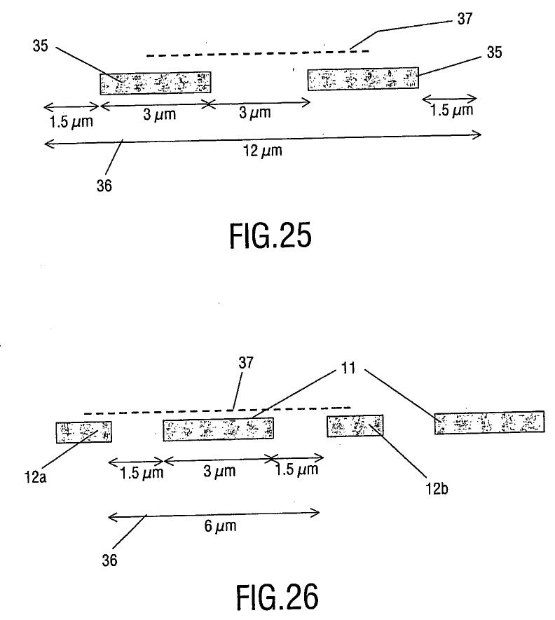

FIG. 25 is a cross section of a sensor described in the prior art and illustrating chip area dimensions.

FIG. 26 is a cross section of a sensor device according to the sixth embodiment of the present invention showing chip area dimensions.

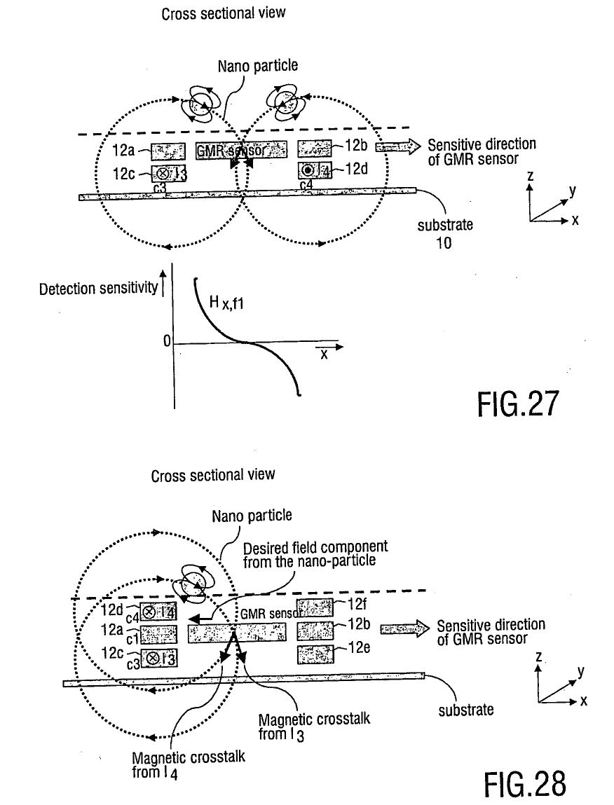

FIG. 27 is a cross sectional view of a sensor device according to a tenth embodiment of the present invention for reducing magnetic cross-talk.

FIG. 28 shows a method of detection corresponding to the tenth embodiment of the present invention shown in FIG. 27.

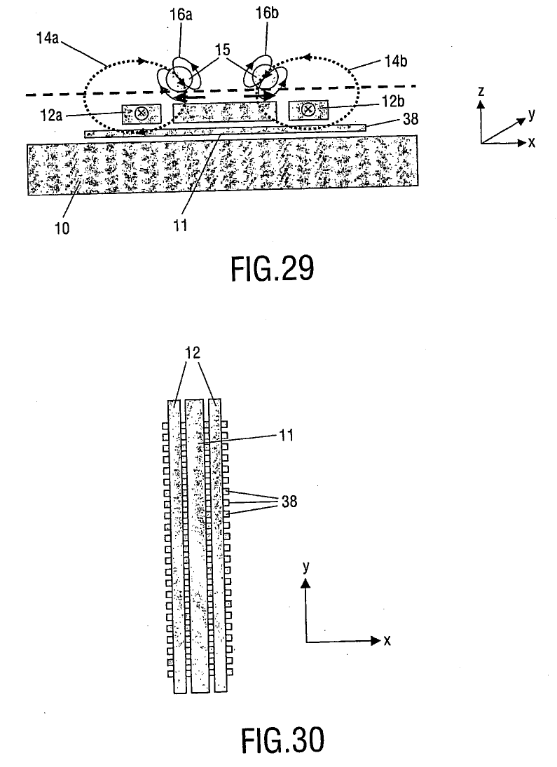

FIG. 29 is a cross sectional view of a sensor device according to the sixth embodiment of the present invention comprising a flux guiding layer.

FIG. 30 is a top view of a sensor device according to the sixth embodiment of the present invention comprising the flux guiding layer of FIG. 29.

In the different figures, the same reference figures refer to the same or analogous elements.

The present invention will be described with respect to particular embodiments and with reference to certain drawings but the invention is not limited thereto but only by the claims. The drawings described are only schematic and are non-limiting. In the drawings, the size of some of the elements may be exaggerated and not drawn on scale for illustrative purposes. Where the term “comprising” is used in the present description and claims, it does not exclude other elements or steps. Where an indefinite or definite article is used when referring to a singular noun e.g. “a” or “an”, “the”, this includes a plural of that noun unless something else is specifically stated.

The magnetic sensor device of FIG. 1 comprises a magneto-resistive sensor element 11 and a magnetic field generator 12 in the form of a conductor.

The level of the capacitive crosstalk between the conductor and the GMR sensor can be estimated. Assuming a geometry as shown in FIG. 1 the capacitance is:

C=∈₀∈ᵣ·l=8.8·10⁻¹²·4·10⁻⁴=3.5fF

Because the capacitive crosstalk is distributed across the GMR sensor, the average crosstalk is modeled by a capacitor value of 1.8 fF as shown in FIG. 2.

When assuming I_{c}=10 mA the voltages across the conductor 12 equals to 1 Volt.

Applying Norton-Thevenin, the equivalent scheme of FIG. 3 appears.

The sensor voltage due to the capacitive crosstalk equals to

$${U}_{CT} = \frac{jω {R}_{GMR} {C}_{c}}{jω ( {R}_{GMR} + {R}_{cond} ) {C}_{c} + 1}$$

This represents a first-order high-pass filter according to the following Bode diagram as shown in FIG. 4.

At a frequency of 100 MHz, the crosstalk voltage

$${U}_{CT} = 0.9 \cdot \frac{{10}^{8}}{8 \cdot {10}^{10}} = 1 mV .$$

This is a substantial signal when a sensitive measurement is required.

Therefore capacitive cross-talk reducing means are required for the detection of magnetic fields in the mV range and below.

In a first example of the present invention the magnetic sensor device is a biosensor. For biosensors the magnetic field that has to be detected is very small. Only one single magnetic nano-particle has to be detected and the measurement signal can be only several μV's.

A biosensor device 50 is represented schematically in FIG. 5A. It comprises a cartridge housing 51, chambers 52 and/or channels for containing the material, e.g. analyte to be analyzed, and a biochip 54. The biochip 54 is a collection of miniaturized test sites (micro-arrays) arranged on a solid substrate that permits many tests to be performed at the same time in order to achieve higher throughput and speed. It can be divided into tens to thousands of tiny chambers each containing bioactive molecules, e.g.—short DNA strands or probes. It can be three dimensional, capable of running as many as 10,000 different assays at the same time. Or, the chip 54 can be manufactured more simply with as few as 10 different assays running at one time. In addition to genetic applications (decoding genes), the biochip 54 is being used in toxicological, protein, and biochemical research, in clinical diagnostics and scientific research to improve disease detection, diagnosis and ultimately prevention.

A biochip 54 comprises a substrate with at its surface at least one, preferably a plurality of probe areas. Each probe area comprises a probe element 55 over at least part of its surface. The probe element 55 is provided with binding sites 56, such as for example binding molecules or antibodies, able to selectively bind a target sample 57 such as for example a target molecule species or an antigen. Any biologically active molecule that can be coupled to a matrix is of potential use in this application.

Examples are:

Nucleic acids: DNA, RNA double or single stranded or DNA-RNA hybrids, with or without modifications. Nucleic acid arrays are well known.

Proteins or peptides, with or without modifications, e.g. antibodies, DNA or RNA binding proteins. Recently, grids with the complete proteome of yeast have been published.

Oligo- or polysaccharides or sugars.

Small molecules, such as inhibitors, ligands, cross-linked as such to a matrix or via a spacer molecule.

The items spotted on the grid will be most likely libraries of compounds, such as peptide/protein libraries, oligonucleotides libraries, inhibitor libraries.

There exist different possibilities to connect magnetic particles to a target sample, examples of which are shown in FIGS. 5B, 5C and 5D. Different types of magnetic particles which can be used with the present invention are described by Urs Häfeli et al. in “Scientific and Clinical Applications of Magnetic Carriers”, Plenum Press, New York, 1597, ISBN 0-306-45687-7.

In FIG. 1B, sensor molecules 58 labeled with magnetic particles 15 are able to selectively bind target sample 57. When random searches are performed, e.g. screening in which DNA binding proteins of a certain tissue extract bind to a grid with a library of nucleotides, the sensor molecule should have a very broad specificity. In this example a sensor molecule with a spacer reactive towards amino groups or carboxy groups would be useful. Other sensor molecules with a reactive group towards sugars, DNA are also suitable. In the case of a direct search, tailor-made sensor molecules can be used e.g. where a screening with a protein against a protein library is performed for assumed protein-protein interaction, an antibody is an obvious choice. Both monoclonal and polyclonal antibodies may be used. As shown in FIG. 1B, magnetic particles 15 are indirectly bound to the target sample 57.

In FIG. 5C, the target sample 57 molecules are directly labeled by magnetic particles 15.

In FIG. 5D, target sample 57 is labeled by labels 60. Such a labeled target sample 57 (e.g. biotinylated sample DNA) is selectively bound to binding sites 56. Sensor molecules 61 (e.g. streptavidin) labeled with magnetic particles 15 are able to selectively bind the labels 60 on the target sample 57. Again, the magnetic particles 15 are indirectly bound to the target sample 57.

The functioning of the biochip 54 is as follows. Each probe element 55 is provided with binding sites 56 of a certain type. Target sample 57 is presented to or passed over the probe element 55, and if the binding sites 56 and the target sample 57 match, they bind to each other. Magnetic particles 15 are directly or indirectly coupled to the target sample 57, as illustrated in FIGS. 1B, 1C and 1D. The magnetic particles 15 allow to read out the information gathered by the biochip 54.

The present invention is about how to read out the information gathered by the biochip 54 by means of a magnetic sensor device. In the following the present invention will be described referring to magneto-resistive devices, such as AMR, GMR or TMR devices, as part of the magnetic sensor device. However, the invention is not limited thereto and can make use of any suitable kind of magnetic sensor element, such as for example a Hall sensor or a SQUID (superconducting quantum interference device).

In a first embodiment the device according to the present invention is a biosensor and will be described with respect to FIG. 6 and FIG. 7. The biosensor detects magnetic particles in a sample such as a fluid, a liquid, a gas, a visco-elastic medium, a gel or a tissue sample. The magnetic particles can have small dimensions. With nano-particles are meant particles having at least one dimension ranging between 0.1 nm and 1000 nm, preferably between 3 nm and 500 nm, more preferred between 10 nm and 300 nm. The magnetic particles can acquire a magnetic moment due to an applied magnetic field (e.g. they can be paramagnetic) or they can have a permanent magnetic moment. The magnetic particles can be a composite, e.g. consist of one or more small magnetic particles inside or attached to a non-magnetic material. As long as the particles generate a non-zero response to the frequency of an ac magnetic field, i.e. when they generate a magnetic susceptibility or permeability, they can be used.

The device may comprise a substrate 10 and a circuit e.g. an integrated circuit. A measurement surface of the device is represented by the dotted line in FIG. 6 and FIG. 7. In embodiments of the present invention, the term “substrate” may include any underlying material or materials that may be used, or upon which a device, a circuit or an epitaxial layer may be formed. In other alternative embodiments, this “substrate” may include a semiconductor substrate such as e.g. a doped silicon, a gallium arsenide (GaAs), a gallium arsenide phosphide (GaAsP), an indium phosphide (InP), a germanium (Ge), or a silicon germanium (SiGe) substrate. The “substrate” may include for example, an insulating layer such as a SiO₂ or an Si₃N₄ layer in addition to a semiconductor substrate portion. Thus, the term substrate also includes glass, plastic, ceramic, silicon-on-glass, silicon-on sapphire substrates. The term “substrate” is thus used to define generally the elements for layers that underlie a layer or portions of interest. Also, the “substrate” may be any other base on which a layer is formed, for example a glass or metal layer. In the following reference will be made to silicon processing as silicon semiconductors are commonly used, but the skilled person will appreciate that the present invention may be implemented based on other semiconductor material device s and that the skilled person can select suitable materials as equivalents of the dielectric and conductive materials described below.

The circuit may comprise a magneto-resistive sensor 11 as a sensor element and a magnetic field generator in the form of a conductor 12. The magneto-resistive sensor 11 may for example be a GMR or a TMR type sensor. The magneto-resistive sensor 11 may for example have an elongated, e.g. a long and narrow stripe geometry but is not limited to this geometry. Sensor 11 and conductor 12 may be positioned adjacent to each other (FIG. 6) within a close distance g. The distance g between sensor 11 and conductor 12 may for example be between 1 nm and 1 mm; e.g. 3 μm. The minimum distance is determined by the IC process.

In FIGS. 6 and 7, a co-ordinate device is introduced to indicate that if the sensor device is positioned in the xy plane, the sensor 11 mainly detects the x-component of a magnetic field, i.e. the x-direction is the sensitive direction of the sensor 11. The arrow 13 in FIG. 6 and FIG. 7 indicates the sensitive x-direction of the magneto-resistive sensor 11 according to the present invention. Because the sensor 11 is hardly sensitive in a direction perpendicular to the plane of the sensor device, in the drawing the vertical direction or z-direction, a magnetic field 14, caused by a current flowing through the conductor 12, is not detected by the sensor 11 in absence of magnetic nano-particles 15. By applying a current to the conductor 12 in the absence of magnetic nano-particles 15, the sensor 11 signal may be calibrated. This calibration is preferably performed prior to any measurement.

When a magnetic material (this can e.g. be a magnetic ion, molecule, nano-particle 15, a solid material or a fluid with magnetic components) is in the neighborhood of the conductor 12, it develops a magnetic moment m indicated by the field lines 16 in FIG. 7. The magnetic moment m then generates dipolar stray fields, which have in-plane magnetic field components 17 at the location of the sensor 11. Thus, the nano-particle 15 deflects the magnetic field 14 into the sensitive x-direction of the sensor 11 indicated by arrow 13 (FIG. 7). The x-component of the magnetic field Hₓ which is in the sensitive x-direction of the sensor 11, is sensed by the sensor 11 and depends on the number Nₙₚ of magnetic nano-particles 15 and the conductor current I_{c}.

A method for detection of magnetic nano-particles, according to an embodiment of the present invention without the cross-talk suppression means, is illustrated in FIG. 8. A modulating signal Mod(t) having a suitable waveform such as a sinusoidal wave (sin at) and with a high frequency of, for example but not limited thereto, 50 kHz, coming from a source 20, is sent to the conductor 12 to modulate the conductor current I_{c}. With a “high frequency” according to the present invention is meant a frequency which does not generate a substantial movement of the magnetic particles at that frequency, for example a frequency of 100 Hz or higher, preferably 1 kHz or higher, more preferred 50 kHz or higher.

The conductor current is modulated such that I_{c}=I_{c} sin at, and this modulated current induces a magnetic field which per se is mainly vertical or z-oriented at the location of the magneto-resistive sensor 11, as shown by the field line 14 in FIG. 6.

A sensing current Iₛ passes through the magneto-resistive sensor 11. Depending on the presence of nano-particles 15 in the neighborhood of the magneto-resistive sensor 11, the magnetic field at the location of the sensor 11, and thus the resistance of the sensor 11 is changed.

FIG. 9 shows the magnetoresistance characteristic of the GMR sensor. Without the presence of magnetic particles, the input signal is the ac magnetic field from the conductor. Depending on the presence of nano-particles 15 in the neighborhood of the magneto-resistive sensor 11, the magnetic field at the location of the sensor 11, and thus the resistance of the sensor 11 is changed. The magnetic field Hₓ in the sensitive x-direction of the magneto-resistive sensor 11 is to a first order proportional to the number Nₙₚ of magnetic nano-particles and the conductor current I_{c}:

Hₓ∝NₙₚI_{c} sin at.

A different resistance of the sensor 11 leads to a different voltage drop over the sensor 11, and thus to a different measurement signal delivered by the sensor 11. The response to the ac magnetic field signal is shown schematically on the left hand side of FIG. 9. The resulting GMR output signal is a continuous wave. The measurement signal delivered by the magneto-resistive sensor 11 is then delivered to an amplifier 21 for amplification thus generating an amplified signal Ampl(t).

This amplified signal Ampl(t) is detected, synchronously demodulated by passing through a demodulating multiplier 22 where the signal is multiplied with the modulation signal Mod(t) (in this case equal to sin at), resulting in an intermediate signal Mult(t), the intermediate signal Mult(t) being equal to:

Mult(t)=NₙₚI_{c} sin²at=NₙₚI_{c}·1/2(1−cos 2at).

In a last step, the intermediate signal Mult(t) is sent through a low pass filter 23. The resulting signal Det(t) is then proportional to the number Nₙₚ of magnetic nano-particles 15 present at the surface of the sensor 11.

Additionally, the amplifier 21 can be AC coupled to the magneto-resistive sensor 11 by means of a low-frequency suppressor such as a capacitor C. The capacitor further enhances the low-frequency suppression.

In the present invention, magnetic particles, e.g. magnetic nano-particles 15, are operated in their linear region 24 which means that the magnetic moment m of the magnetic particles 15 linearly follows the magnetic field strength (FIG. 10). This also means that only a small magnetic field is required to induce a magnetic moment in the nano-particles 15. For example, for nano-particles having a diameter of 50 nm, the full linear range 24 of the magnetic moment m versus the magnetic field can amount from −0.015 Am²/g to +0.015 Am²/g, requiring from −10 kA/m to +10 kA/m magnetic field strength. In case that magnetic nano-particles 15 are operated in the saturated region 25 a much higher magnetic field is required, i.e. at least 80 kA/m. From FIG. 6 the signal loss in linear versus saturated operation can be calculated and equals mₗᵢₙ/mₛₐₜ=0.015/0.025=0.6.

In the proposed embodiment, a magnetic moment is induced by a magnetic field with low field strength, which in its turn is induced by a magnetic field generator such as a current flowing in a conductor 12. If, in a specific example, the sensor 11 has an elongated, i.e. long and narrow, stripe geometry and the distance between the conductor 12 and the sensor 11 is g=3 μm, with a conductor current with an amplitude I_{c}=20 mA, the vertical field strength equals H_{z}=I/2πw≈1 kA/m. A detailed view of the magnetization curve of FIG. 10 shows that the magnetization at 1 kA/m equals 0.0015 Am²/g (FIG. 11). With respect to the saturated case, the detected signal has decreased by a factor 0.0015/0.025=0.06.

In the first embodiment, but this time with cross-talk suppression means, a slightly different detection method for the detection of magnetic particles 15 is described. This embodiment is illustrated schematically in FIG. 12. An aim of this embodiment is to uncouple the parasitic differential capacitive coupling between the conductor 12 and the sensor 11 from the measurement. The capacitor 28 models the parasitic differential capacitive coupling between the conductor 12 and the sensor 11.

A modulating signal, Mod(t) which may be a sinusoidal wave (sin at) at a high frequency of 500 Hz or higher, delivered from modulation source 20, feeds both the conductor 12 and the sensor 11, hence:

I_{c}=I_{c} sin at

Iₛ=Iₛ sin at

The high frequency current I_{c} in the conductor 12 induces a magnetic field in the sensor element 11. Because of the fact that the GMR sensor is exclusively sensitive to magnetic fields, only the magnetic component (and not the parasitic capacitive cross-talk) of the measurement signal of the sensor 11 is multiplied by the sensor current Iₛ. After amplification in amplifier 21, the amplified signal Ampl(t) becomes:

Ampl(t)=Nₙₚ(I_{c} sin at)·(Iₛ sin at)+αI_{c} sin at+IₛI_{R} sin at

The second term in this formula represents the capacitive cross talk between the sensor 11 and the conductor 12. The third term results from the sensor voltage induced by the sensor current Iₛ into the sensor resistance. Further reduction of the last formula provides:

Ampl(t)=Nₙₚ·I_{c}·Iₛ·1/2(1−cos 2at)+αI_{c} sin at+IₛRₛ sin at

After low-pass filtering, a signal proportional to the number of nano-beads remains.

However, in this embodiment, the 1/f noise originating from amplifier 21 is not removed because the modulation process takes place before amplification. A possible solution for this problem is demodulation of the second harmonic frequency after sending the amplified signal Ampl(t) through a band pass filter 29 with central frequency 2f, as shown in FIG. 13. By doing so, the electronic 1/f noise sources are suppressed. After passing through a demodulating multiplier 22 and a low pass filter 23, the resulting signal Det(t) is formed, which is proportional to the number Nₙₚ of nano-particles 15 present in the neighborhood of the sensor 11.

In an improved second embodiment of the present invention, detection of magnetic particles, for example magnetic nano-particles 15 in a biosensor, is described, making use of non-integer modulation frequencies f_{mod} from source 20a and f_{demod} from source 20b. In embodiment 1, higher order harmonics (distortion) present in I_{c} and Iₛ will lead to base-band components. Therefore it is advantageous to use frequencies f_{Ic} and f_{Is}, which show a non integer relationship, as is illustrated in by means of the detection circuit of FIG. 14. The amplified signal is sent through a band-pass filter 30 with central frequency f_{mod}−f_{demod}. An extra modulation step at frequency f_{mod}−f_{demod} generates the desired base-band signal Det(t). As a variant, f_{mod}+f_{demod} can be detected instead of f_{mod}−f_{demod}.

The separation of the capacitive cross-talk and the desired magnetic signal in the frequency domain was explained in the first and second embodiments. Alternatively, the capacitive signal and the desired magnetic signal can be distinguished in phase, amplitude and time.

In a third embodiment, illustrated in FIG. 15A, an alternative detection method based on the separation of the capacitive signal and the desired magnetic signal in phase is described. The phase and the amplitude of the capacitive signal depend heavily on the circuit layout and the values of the distributed resistances and capacitances.

Mostly, the cross talk phase appears to be between 60 and 120 degrees.

In order to remove the parasitic capacitor 28 between the conductor 12 and the sensor 11, the sensor device now comprises electrical phase distinguishing means 50 such as a synchronous demodulator 52 and a phase locked loop (PLL) 54 or a delayed lock loop (DLL) 56.

An adaptive system adjusts the phase of a synchronous demodulator orthogonal to the phase of the capacitive cross talk signal at zero sense current of the magnetic sensor. Then a DC bias current is applied to the magnetic sensor and the sensor output signal is synchronously demodulated while maintaining the previously adjusted phase. This measure removes the capacitive cross talk from the sensor signal.

At least one time per bio-measurement the following steps are performed:

By setting the sensor bias-current to zero, only the capacitive cross talk at frequency f₁ remains at the output of amplifier 21. By means of a Phase Locked Loop (PLL) system 54, the phase of a Voltage Controlled Oscillator (VCO) is locked to the output signal. Because of the properties of the phase detector (PD), which is implemented as an XOR or multiplier, 90 degrees phase difference between the VCO and the capacitive cross talk is maintained.

Subsequently a DC bias current Iₛ is applied to the magnetic sensor and the phase of the VCO is frozen. The output signal of the magnetic sensor now containing the desired magnetic signal plus the capacitive cross talk, is synchronous demodulated using the VCO signal as a reference. Because the VCO phase is set orthogonal to the capacitive cross talk, the capacitive cross talk is suppressed in the demodulated signal. The zero order hold function holds the demodulator output during the time step 1 is executed.

These steps may be performed in an alternating way in order to maintain sufficient accurate phase lock.

Alternatively, the PLL may comprise a quadrature VCO and a zero-phase phase detector (see FIG. 15b). The quadrature VCO generates both an in-phase signal (VCO_I) and a 90 degrees out-of-phase signal (VCO_Q). The phase detector generates zero output at zero degrees phase difference.

Similar to the VCO in FIG. 15A, VCO_I is phase locked to the capacitive cross talk signal during the time that the sense current Iₛ is set to zero. Due to the properties of the phase detector, the phase difference between these signals is zero degrees.

Demodulation takes VCO_Q as a reference, which signal is perfectly orthogonal to the capacitive cross talk.

It is also possible that a Delay Locked Loop (DLL) 56 shifts the demodulator phase (see FIG. 15C). Compared to the previous phase locked loops the DLL has the advantage of faster lock-in times, of higher accuracy (less phase noise) and of prevention of false lock situations.

The DLL may comprise a zero-phase phase detector (see FIG. 15D). A quadrature oscillator generates both an in-phase signal (Osc_I) and a 90 degrees out-of-phase signal (Osc_Q). Two identical variable delay lines are controlled by loop filter in the DLL.

In an alternative example, the capacitive cross talk is reduced by a subtraction method using a comb filter 58 as shown in FIG. 16A. This method has the advantage compared to the previous embodiments of FIG. 15A-D that more spectral components of the capacitive cross talk signal can be removed from the desired signal. This is advantageous in case that non-sinusoidal excitation currents are applied.

The comb filter comprises a feedback delay line having a length of τ_{delayline}=1/f₁, where f₁ is the frequency of the first harmonic of the capacitive crosstalk signal to be removed.

During the time that Iₛ is set to zero, the content of the delay line is adapted until the spectral components at multiples of frequency f₁ in the output signal of amplifier 21 are zero. After applying the sense current Iₛ the content of the comb filter 58 is frozen and subtracted from the output signal so that the capacitive cross talk is removed.

In order to limit the dynamic range of the pre-amplifier 21, the capacitive crosstalk is removed at the input of said amplifier (see FIG. 16B).

A practical implementation of this embodiment may be achieved by using digital techniques (see FIG. 16C).

In a fourth embodiment the capacitive cross talk subtraction is based on the difference in amplitude of the cross-talk signal as a function of frequency.

The current Ic through the conductor 12 comprises at least two frequency components, namely a relatively low frequency f₁ and a relatively high frequency f₂. Because the desired magnetic signal is relatively frequency independent for frequencies under the relaxation- and re-magnetisation bandwidth of the beads, the amplitude of the magnetic signal will be the same at both frequencies. The capacitive cross talk, however, is frequency dependent. This is illustrated in FIG. 17A. In case that f₂ is one decade higher than f₁, then the contribution of the capacitive cross talk to the amplitude of the signal at frequency f₂ will be 10 times higher then at frequency f₁. A weighted subtraction of 10 times the amplitude at f₁ from the amplitude at f₂ cancels the capacitive cross talk and results in 9 times the magnetic signal from the beads. For clarity, the next graph depicts the frequency dependence of both the capacitive cross talk signal and the desired magnetic signal. Also depicted is the subtraction of the signal at two frequencies, resulting in a signal of just magnetic origin.

This method is schematically represented in FIG. 17B. U_{o,CT+beads} represents the output signal of the sensor, having a capacitive cross talk component and a magnetic bead component, both at frequency f₁ and f₂. Demodulating this signal twice in parallel, once with a signal having a frequency f₁ and once with a signal having a frequency f₂, results, among others, in two DC signals. An amplification of the signal from f₁ with a factor 10 and a subsequent subtraction of both DC signals results, after low pass filtering, in a signal consisting of just the magnetic bead signal (9×U_{o,beads}).

If we assume that the capacitive cross talk will not change during the actual bio-measurement, which is a safe assumption at least in the case of integrated field generation, the capacitive cross talk can also be canceled after performing said measurements. Prior to the actual bio-measurement, when no beads are present yet, the capacitive cross talk signal is measured and its amplitude stored. After performing the actual bio-measurement the stored value is subtracted from the measured signal, thereby removing the cross talk and obtaining just the signal from the beads.

In the embodiments 1 to 4, the detection SNR of the integrated excitation method is limited by the allowable power dissipation in the GMR sensor.

At constant power dissipation, sense current modulation requires a factor of \sqrt{8} more supply voltage compared to the un-modulated (DC) situation. The relation between the peak-to-peak value and the effective value of the current causes this. As IC-processes are voltage limited, the effective value of the sense-current and thus the achievable detection SNR is much smaller compared to the un-modulated case.

In order to limit the dynamic range of the GMR amplifier 21, subtraction of the capacitive cross talk may be implemented directly in the amplifier.

The invention is also applicable to biosensors other amplifier configurations than disclosed.

In a fifth embodiment, illustrated in FIG. 18, an alternative detection method to the method described in the embodiments mentioned above are described. In order to remove the parasitic capacitor 28 between the conductor 12 and the sensor 11, the sensor device now comprises a physical cross-talk suppression means such as an electrostatic shield 31 between the conductor 12 and the sensor 11 (FIG. 18), which shield is connected to a fixed voltage, e.g. ground. The purpose of this electrostatic shield 31 is to avoid or reduce the capacitive cross-talk between sensor 11 and conductor 12. Hence, the electrostatic shield 31 may be any device, which attenuates coupling between the conductor 12 and the sensor 11. This electrostatic shield 31 can be implemented by a conductive layer 39 between conductor 12 and sensor 11, as illustrated in FIG. 19, which conductive layer 39 is connected to a fixed voltage such as ground. The conductive layer 39 is electrically isolated from both the conductor 12 and the sensor 11 by isolation means such as e.g. a layer 40 of insulating material.

Because the biosensor as described in the embodiments 1 to 5 is very sensitive, the magnetic particles used do not need to be large; they may have a small magnetic moment as no movement of the magnetic particles is needed for detection. Also detection can be carried out both during application of the magnetic field or during relaxation thereof, so it is not necessary to provide large particles having a sufficiently long relaxation time.

A further advantage is the possibility to perform several measurements in parallel, instead of successively. This is due to the fact that the magnetic field of each conductor is locally concentrated, so different magnetic fields (frequency, amplitude, etc.) can be used on different spots.

Accuracy of (bio)sensors can be enhanced by knowing information about the concentration of magnetic particles as a function of position. By using any of the methods according to the present invention as described above, only the amount of magnetic particles 15 may be determined.

In a sixth embodiment, a device and method are described for determination of the concentration of magnetic material (e.g. nano beads) as a function of the location compared to the sensor 11.

A device according to this embodiment may comprise an integrated circuit having a magnetic sensor element 11, which may be, for example, a magneto-resistive sensor element such as e.g. a GMR or a TMR sensor element, and two conductors 12a-b, each at one side of the sensor element 11. A device according to this embodiment is illustrated in FIG. 20.

FIG. 20 shows a cross sectional view of a device according to this embodiment. If the sensor device is positioned in the xy plane, the sensor 11 only detects a component of the magnetic field in a certain direction e.g. the x-component of a magnetic field, i.e. the x direction is the sensitive direction of the sensor 11. The sensitive direction is indicated by the arrow 13. Hence, magnetic fields 14a, 14b, caused by currents I₁ and I₂ flowing through the conductors 12a respectively 12b, will not be detected by the sensor 11 in absence of magnetic particles 15 as they are oriented in the z-direction at the location of the sensor 11.

In case magnetic particles, such as e.g. nano-particles 15, are present at the surface of the sensor 11, they each develop a magnetic moment m indicated by the field lines 16a, 16b in FIG. 19. The magnetic moments m generate dipolar stray fields which have in-plane magnetic field components 17a, 17b at the location of the sensor 11.

The z-component of the magnetic field H_{z} is roughly proportional to 1/x, or thus inversely proportional to the distance x between the magnetic particle 15 and the conductor. Therefore, the sensitivity of the detection mechanism depends on the position of the magnetic particle 15 at a particular position in the xy plane. More specifically, the responses of a magnetic particle 15 to currents I₁ and I₂ in the respective conductors 12a, 12b depend on the x-position of the magnetic particle 15 in the xy-plane, which can be seen from the graph in the lower part of FIG. 20. In this graph, the in-plane field strengths H_{x,1} and H_{x,2} induced by a magnetic particle 15 at position x in the xy plane in response to the conductor currents I₁ and I₂ is depicted.

By measuring H_{x,1} and H_{x,2} by time-, frequency- or phase (quadrature) multiplex techniques, the x-position of the magnetic particle 15 can be derived.

An anti-phase current in conductor 12b compensates the cross-talk signal originating from conductor 12a at frequency f₁. Likewise an anti-phase current in conductor 12a compensates the crosstalk from conductor 12b. An additional effect of this sixth embodiment is that the net field distribution sensor device changes towards an odd function.

FIG. 20 shows the field characteristic at frequency f1.

When the distance increases between the conductor (12a, 12b) and the sensor element (11), the magnetic field with respect to the surface plane of the magnetic sensor element (11) will become more perpendicular. This means that a magnetic nano-particle will become magnetized more perpendicularly. This results in a decrease in output response of the GMR sensor. The sensitivity of detection will therefore decrease more rapidly than 1/x, as mentioned here above.

The present invention includes within its scope sensors measuring more than one magnetic bead 15. In case a plurality of magnetic particles 15 are present, the sensor 11 measures an integral over the magnetic particle concentration as a function of the x-position of the sensor 11.

The magnetic particle concentration is determined as a function of the x-position by a frequency multiplex method, which is illustrated in FIG. 21. An anti-phase current in conductor 12B compensates the cross-talk signal originating from conductor 12a at frequency f1 shown in FIG. 20. Likewise an anti-phase current in conductor 12a compensates the crosstalk from conductor 12b. An additional effect of this embodiment is that the net field distribution sensor device changes towards an odd function. FIG. 20 shows the field characteristic at frequency f1.

In FIG. 21 a first modulating signal Mod₁(t) is sent from a first source 20a to the first conductor 12a to modulate the current I₁ and is sent to a first demodulating multiplier 22a. The modulated current I₁ which flows through the conductor 12a induces a magnetic field, shown by field lines 14 in FIG. 19, which is mainly oriented perpendicular to the plane of the sensor element 11 at the location of the sensor 11. When magnetic particles 15 are present in the neighborhood of the sensor 11, the magnetic field at the location of the sensor 11 and thus the resistance of the sensor 11 is changed. The change of resistance gives rise to a different voltage drop over the sensor 11 and hence a different measurement signal delivered by the sensor 11. The measurement signal is sent through an amplifier 21 and the amplified measurement signal Ampl(t) is demodulated with the first modulating signal Mod₁(t). The resulting first intermediate signal Mult₁(t) is then sent through a first low pass filter 23A to form a first detection signal Det₁(t).

The current I₂ in the second conductor 12b is modulated by a second modulating signal Mod₂(t). The second modulating signal is sent to a second demodulating multiplier 22B where it is demodulated with the amplified measurement signal Ampl(t), thus forming a second intermediate signal Mult₂(t). The second intermediate signal Mult₂(t) is then sent through a second low pass filter 23b to form a second detection signal Det₂(t).

Both first and second detection signals Det₁(t) and Det₂(t) are applied to an interpreting means 34. These first and second detection signals Det₁(t) and Det₂(t) are a measure of the magnetic particles concentration in the sphere of influence of resp. I₁ and I₂. By interpreting these two detection signals Det₁(t), Det₂(t), information about the concentration distribution of the magnetic particles 15 may be retrieved.

A normalized difference signal PosX is given by:

$$PosX = \frac{{Det}_{1} ( t ) - {Det}_{2} ( t )}{{Det}_{1} ( t ) + {Det}_{2} ( t )}$$

and is representative for the average x-position of the magnetic particles 15.

The sum signal SUM=Det₁(t)+Det₂(t) is a measure for the total number of magnetic particles 15, their magnetization (diameter, permeability) and their position in a direction perpendicular to the plane of the sensor element 11, in the present case their z-position.

The ratio:

$$R = \frac{{Det}_{1} ( t )}{{Det}_{2} ( t )}$$

can also be used as an indication for the position of the magnetic particles 15 with respect to the sensitive direction of the sensor element 11, in the present case the x-position.

In case the frequency of Mod 1 and Mod 2 are the same, the magnetic field is zero in the middle of the sensor. By varying the amplitude balance of the two currents, the zero-point will shift along the x-axis. In this way additional information can be gathered about the particle distribution.

As a result this configuration measures the differential bead concentration on the sensor. When this is not desirable surface patterning is required. Ideally, the geometry is symmetrical and easy subtracting the inverse currents will be sufficient.

Alternatively subtraction of the compensation currents can also further in the processing chain, e.g. just before the amplifier or before the signal processing means.

In case of non-symmetrical cross-talk the amplitude (or phase) of the compensation current in the opposite conductor must be aligned. This can be implemented via adaptive techniques using synchronous detection of the GMR signal in order to determine the optimum compensation currents where the cross-talk is minimal.

FIG. 22 shows a seventh embodiment for reducing the capacitive cross-talk without affecting the magnetic field. For didactic reasons one half of the detection schema is depicted, namely only that part that measures at frequency f1. An anti-phase voltage in conductor 12b compensates the capacitive crosstalk signal originating from the current in Conductor 12a at frequency f1. For this purpose the ground connection of Conductor 12b is removed so that no current can flow to ground. Measuring at f2 is performed in an analogous way by disconnecting the ground connection from Conductor 12A and feeding an anti-phase voltage to Conductor 12a.

FIG. 23 shows an alternative eighth embodiment for reducing the capacitive crosstalk without affecting the magnetic field. The currents at frequency f1 and f2 through Conductor 12a and Conductor 12b are defined by the current sources I1 and I2. The voltage sources apply the inverse voltages to the adjacent conductors in order to compensate for the capacitive cross-talk.

Due to tolerances in the IC-process, the optimal settings for the cross-talk reducing means can differ between chips. Therefore a calibration procedure is mostly necessary in order to generate the optimal preset values for the cross-talk reducing means.

These preset values are stored in storage means in the form of a memory present at the chip. At this point three scenarios exist. At first, the preset values can be determined by a calibrating procedure prior to the measurement. Environmental circumstances (e.g. temperature) can be included in the calibration. In that case the chip or the reader station comprises adaptive means. At second, the preset values are determined and stored into the memory means at chip manufacturing.

At third, the start values for the adaptation algorithm are determined at chip manufacturing and stored into the memory means in order to accelerate the adaptation algorithm 35 prior to the measurement.

FIG. 24 shows this ninth embodiment for on-chip storage of cross-talk settings.

The memory means 33 can comprise the preset values for the cross-talk reducing means. They can originate from an on-chip adaptive optimization algorithm or from a source outside the chip. An analog-to-digital converter 32 converts the digital data from the memory into essential preset signals, e.g. gain and phase for the cross-talk reducing means.

The biosensor can comprise a plurality of GMR sensors and depending on the grade of multiplexing one or more signal processing blocks.

This embodiment is not limited to particular storage means. Every appearance of storage, e.g. ROM, RAM, EEPROM, MRAM and laser calibration of the chip's geometry is part of the invention.

An advantage of the device described in the sixth embodiment above is that, in contrast to prior art techniques, the total chip area can be used for measurements. As a result hereof the chip area may be reduced with respect to the devices of the prior art. In FIG. 25 a cross-sectional view of a part of a sensor device according to the prior art of WO 03054523 is shown. The figure pictures only one half of a full Wheatstone bridge configuration used in the prior art. The sensor elements 35 are positioned next to each other at a distance of e.g. 3 μm. At the side opposite to the neighboring sensor element 35, 1.5 μm is left open. From the above it becomes clear that a 2*12 μm=24 μm strip width 36 is required to perform a single test. The bio-sensitive area 37, i.e. the working area of the device is 6 μm, as indicated in FIG. 22.

In the above described sixth embodiment of the present invention (FIG. 20) a bio-sensitive area 37 is achieved with a device a with strip width 36 of 6 μm (FIG. 26). A sensor element 11 is positioned in between two conductors 12a, 12b. If, for example, the sensor element 11 has a width of 3 μg/m as in the prior art device, and the distance between the edge of the sensor 11 and the middle of a conductor 12a, 12b is 1.5 μm, a total strip width of 6 μm is achieved. With respect to the prior art, the chip area may be reduced with a factor of 4, namely 2 times 12 μm versus 6 μm.

In a seventh embodiment of the present invention, an improved sensor device with respect to the previous embodiment is described. In order to distinguish between surface- and bulk concentrations of magnetic particles 15, resolution in a direction perpendicular to the plane of the sensor element 11, which corresponds to the z-direction with the co-ordinate device introduced in FIG. 26, is required. As shown in FIG. 27 conductors 12c and 12d generate a magnetic field 14c and 14d respectively in comparison with the magnetic field 14a and 14b of conductors 12a and 12b. By combining the sensor signals originating from the four conductors 12a, 12b, 12c, 12d, information may be obtained about the concentration of the magnetic particles 15 in x and z direction.

Reduction of the capacitive and the magnetic cross-talk becomes an important issue when measuring at high frequencies.

Magnetic cross-talk occurs when a conductor generates a magnetic field component into the sensitive direction of the magnet resistive sensor. For example this occurs when there is a z-displacement between the sensor and the conductor, as shown in FIG. 27.

Due to the asymmetric configuration, current I₃ introduces a magnetic field component in the sensitive x-direction of the sensor. Adding current I4 in conductor c4 (12d) compensates the magnetic cross-talk.

The z-resolution can be further enhanced by applying more conductors in the direction perpendicular to the plane of the sensor element 11, which as represented is the vertical or z direction. This is shown in the eighth embodiment in FIG. 28. Conductors 12a and 12b are positioned at both sides next to the magnetic sensor 11, at the same level in a direction perpendicular to the plane of the sensor element 11. Conductors 12c, 12d are at a different z-position with respect to conductors 12a and 12b.

The currents in conductors 12c and 12d have the same directions.

Due to the symmetrical configuration the x-components of the magnetic fields from currents I₃ and I₄ cancel in the sensor, so that the magnetic crosstalk is reduced. The response of the nano-particles on the fields from currents I₃ and I₄ add-on.

On this theme, many variations are possible. Again, combination of the sensor signals resulting from the different conductors 12a to 12f may give information about the bulk and surface concentration of the magnetic particles 15.

Furthermore parasitic magnetic elements can appear in integrated sensor due to the form factor of the elements of the sensor and the constraints (design rules) of the IC process.

Analogous to the previous embodiments adaptive techniques may be used to determine the optimal amplitude and phase of the currents in the conductors for minimal magnetic cross-talk. Furthermore geometry changes due to process tolerances will make adaptive techniques necessary.

When in the above embodiments large conductors 12 are used, as for example a sheet of copper or the like, eddy currents may be generated. An eddy current is a current which is induced in little swirls (‘eddies’) on a large conductor. If this large conductor 12 is positioned in the neighborhood of a magnetic field which intersects perpendicular to the conductor 12, the magnetic field will induce small ‘rings’ of current which will create internal magnetic fields opposing the change.

Eddy currents induced in resp. conductors 12a and 12b by the magnetic field which is in its turn induced by the conductor currents I1 and I2, frustrate the magnetic behavior above the sensor. This effect can be reduced by increasing the distance between the conductors 12a-b and the substrate 10 and by applying for example a high ohmic substrate or a substrate having a relatively small dielectric constant like glass.

As an example, in the sixth embodiment of the present invention eddy currents can be avoided. Between the substrate 10 and the sensor 11 and conductors 12a and 12b a flux guiding layer 38 such as a soft magnetic layer is placed (see a cross-sectional view in FIG. 29 and a top view in FIG. 30). In that way, the substrate 10 is shielded by the flux guiding layer 38, which preferably is laminated in order to avoid eddy currents.

In the embodiments 6 to 9 it is assumed that the position of a magnetic particle 15 does not change during the field scan measurement involving that magnetic particle 15. This assumption can be made because of the slow diffusion and the weak magnetic forces imposed by the current in the conductors 12a-12f.

The diffusion constant of a single magnetic bead, with a diameter of for example 100 nm, in an infinite volume of an aqueous solution at room temperature equals, according to the Stokes-Einstein formula, to:

$$D = \frac{kT}{6 πη R} = \frac{1.38 \cdot {10}^{- 23} \cdot 300}{6 π \cdot {10}^{- 3} \cdot 50 \cdot {10}^{- 9}} = 4.4 \cdot {10}^{- 12} {m}^{2} \text{/} s$$

From the formula a diffusion coefficient with a low value is achieved. When now applying for example a 10 MHz wobble frequency, the traveled distance of a magnetic particle 15 in one direction during 1 wobble period equals:

L=\sqrt{2Dt}=\sqrt{2·4.4·10⁻¹²·10⁻⁷}=1 nm

Assuming now 100 wobble periods per measurement, the displacement of the 100 nm nano-particles 15 equals 10 nm.

The magnetic force due to a magnetic field on a magnetic particle 15 can be encapsulated in a general formula:

$$F = ∇ ( mB ) \approx m ∇ B = m \frac{\partial B}{\partial w} = m \frac{\partial ( \frac{{μ}_{0} I}{2 π w} )}{\partial w} = - m \frac{{μ}_{0} I}{2 π {w}^{2}}$$

If, for example, a 50 nm bead 15 is considered, and the magnetic moment m due to a current in the conductor 12 (I_{c}=20 mA) m≈6·10⁻¹⁴ Am², then for a sensor with GMR strip width w=3 Am, the magnetic attraction force equals:

$$F = 6 \cdot {10}^{- 18} \cdot \frac{4 π \cdot {10}^{- 7} \cdot 0.02}{2 π \cdot {( 3 \cdot {10}^{- 6} )}^{2}} = 2.7 fN$$

The velocity of a single particle 15 in an aqueous liquid as a result of the external force F equals:

$$v = \frac{F}{6 πη R} = \frac{2.7 \cdot {10}^{- 15}}{6 π \cdot {10}^{- 3} \cdot 50 \cdot {10}^{- 9}} = 2.9 μ m \text{/} s$$

In the situation where the particle 15 is actuated by the field of a single conductor 12 during 100 wobble periods, the displacement equals

$$x = v \cdot \frac{100}{f} = 2.9 \cdot {10}^{- 6} \cdot \frac{100}{{10}^{7}} = 30 pm$$

Therefore, this displacement may be neglected during performance of the measurements.

The device and method described by the numerous embodiments of this invention have several advantages with respect to the prior art. First, the method has a small form factor. This means that only a small volume needs to be magnetized, which means that there is a low power consumption. Another advantage is the low power consumption due to the sensor being integrated. Yet another advantage is that the detection method makes it possible to use sensor devices which require no surface structuring of the sensor device surface due to local field application. Nevertheless, surface patterning may be applied and will give additional benefits, such as e.g. no unnecessary loss of target molecules far away from the sensor.

Furthermore, a smaller chip area may be achieved, because 100% of the chip area may be used as bio-sensitive area or working area. Using the method according to the present invention, it is possible to make a distinction between surface and bulk concentration of magnetic particles 15 because of the spatial resolution in x and z direction. It is to be understood that although preferred embodiments, specific constructions and configurations, as well as materials, have been discussed herein for devices according to the present invention, various changes or modifications in form and detail may be made without departing from the scope and spirit of this invention.

For example, the present invention is not restricted to a single magneto-resistive sensor 11 but can also be applied in case of detection of magnetic particles 15 in multi-array biosensors. In that case a surrounding sensor element 11 may fulfill the functionality of conductor 12. This has the advantage that no extra conductor(s) 12 is/are necessary in a multi-assay bio-chip.

1. A magnetic sensor device comprising a magnetic sensor element (11) on a substrate (10), at least one magnetic field generator (12) for generating a magnetic field on the substrate (10), characterized in that cross-talk suppression means (2) are present for suppressing cross-talk between the magnetic sensor element (11) and the at least one magnetic field generator (12).

2. A magnetic sensor device as claimed in claim 1, in which the device is suited to detect the presence of at least one magnetic particle (15), the device further comprising a sensor circuit (3) comprising the magnetic sensor element (11) for sensing a magnetic property of the at least one magnetic particle (15) which magnetic property is related to the generated magnetic field.

3. A magnetic sensor device according to claim 1, wherein the cross-talk suppression means (2) comprises and electrostatic shielding device (31) between the magnetic sensor element and the magnetic field generator.

4. A magnetic sensor device according to claim 1, the at least one magnetic field generator (12) having a first frequency and the magnetic sensor element (11) having a second frequency, wherein the cross-talk suppression means (2) comprises electrical frequency distinguishing means (23) for distinguishing between the first frequency and the second frequency.

5. A magnetic sensor device according to claim 1, the at least one magnetic field generator (12) having a first frequency and a first phase and the output signal of the magnetic sensor element (11) having the first frequency and a second phase equal to the first phase and a phase shift caused by the cross-talk, wherein the cross-talk suppression means (2) comprises electrical phase distinguishing means (50) for distinguishing between the first phase and the second phase.

6. A magnetic sensor device according to claim 1, wherein the magnetic field generator (12) comprises a conductor and an ac current source for generating an ac current flowing through the conductor.

7. A magnetic sensor device according to claim 6, wherein the direction (30) of the ac magnetic field is mainly perpendicular to the plane of the magnetic sensor element in the direct neighborhood of the magnetic sensor element.

8. A magnetic sensor device according to claim 1 wherein a further magnetic field generator (12b) generates a second signal with a third frequency for compensating the cross-talk signal originating from the at least one magnetic field generator (12a) having the first frequency.

9. A magnetic sensor device according to claim 1 wherein a further magnetic field generator (12b) has an anti-phase current or an inverse voltage for compensating the cross-talk signal originating from the at least one magnetic field generator (12a) having the first frequency.

10. A magnetic sensor device according to claim 1, wherein said at least one magnetic field generator (12) and said magnetic sensor element (11) are positioned adjacent each other above a substrate (10).

11. A magnetic sensor device according to claim 7, wherein said at least one magnetic field generator (12) is positioned between said substrate (10) and said magnetic sensor element (11).

12. A magnetic sensor device according to claim 8, the magnetic sensor element (11) lying in a plane, wherein said magnetic field generator (12) is positioned adjacent one side of the magnetic sensor element (11) and the further magnetic field generator (12′) is positioned on the opposite side of the magnetic sensor element (11) at a same position with respect to a direction perpendicular (30) to the plane of the magnetic sensor element (11).

13. A magnetic sensor device according to claim 9, the magnetic sensor element (11) lying in a plane, wherein said magnetic field generator (12) is positioned adjacent one side of the magnetic sensor element (11) and a further magnetic field generator (12′) is positioned on the opposite side of the magnetic sensor element (11) at a same position with respect to a direction parallel to the plane of the magnetic sensor element (11).

14. A magnetic sensor device according to claim 13, furthermore comprising means for determining a concentration of magnetic particles.

15. A magnetic sensor device according to claim 14, wherein the means for determining a concentration of magnetic particles comprises a plurality of magnetic field generators.

16. A magnetic sensor device according to claim 15, the magnetic sensor element lying in a plane, wherein the plurality of magnetic field generators are located at different levels with respect to the plane of the magnetic sensor element.

17. A magnetic sensor device according to claim 16, wherein a flux guiding layer (38) is positioned between the magnetic sensor element and the at least one magnetic field generator on the one hand, and a substrate on the other hand.

18. A magnetic sensor device according to claim 17, wherein the magnetic field generator (12) and the sensor circuit (3) form an integrated circuit.

19. A magnetic sensor device as claimed in claim 18, wherein the sensing circuit (3) comprises a storage means (33).

20. A magnetic sensor device according to claim 19, wherein said magnetic sensor element is a magneto-resistive sensor element.

21. A magnetic sensor device according to claim 20, wherein the at least one magnetic particle (15) is a magnetic label coupled to a biological molecule.

22. Use of the magnetic sensor device as claimed in claim 21 for molecular diagnostics biological sample analysis, or chemical sample analysis.
